(19) United States
(12) Patent Application Publication
(10) Pub. No.: US 2007/0117311 A1
(43) Pub. Date: May 24, 2007

(54) Three-dimensional single transistor semiconductor memory device and methods for making same

(75) Inventor: Rownak Jyoti Zaman, Austin, TX (US)

Correspondence Address: FULBRIGHT & JAWORSKI L.L.P., 600 CONGRESS AVE., SUITE 2400, AUSTIN, TX, 78701, US

(73) Assignee: Advanced Technology Development Facility, Inc.

(21) Appl. No.: 11/286,704

(22) Filed: Nov. 23, 2005

(51) Int. Cl. H01L 21/8242; H01L 29/76

(52) U.S. Cl. 438/253; 257/314

(57) ABSTRACT

Single-transistor memory cell including a three-dimensional capacitor and methods for fabricating the cell are disclosed. The method includes steps for defining a source and drain, forming a channel between the source and drain, and forming a gate area of a transistor. The method also includes forming a first and second capacitor plate of a three-dimensional capacitor coupled to the drain of the transistor. In one respect, the first capacitor plate may be formed substantially simultaneously with the step of forming the channel. Additionally, the second capacitor plate may be formed substantially simultaneously with the step of defining the gate area of the transistor. The capacitor may include a three-dimensional fin capacitor and the transistor may include, for example, a multi-gate field effect transistor, a fin field effect transistor, a tri-gate transistor, a Π transistor, and a Ω transistor.

### BACKGROUND OF THE INVENTION

1. Field of the Invention

The present invention relates generally to semiconductor devices and fabrication, and more particularly a single-transistor memory device coupled to a three dimensional capacitor and methods for fabricating the same.

2. Description of Related Art

Semiconductor memory devices, in particular, random access memory devices, generally employ capacitors, which have the ability to retain a charge. This ability allows the capacitor to “remember” an energy level over a period of time, and thus can store data to be retrieved when needed.

One example of random access memory devices includes a dynamic random access memory (DRAM). In a DRAM cell, charge stored on a planar capacitor of the memory cell does not remain on the planar capacitor indefinitely due to a variety of leakage paths, which causes the memory cell to lose the data. To alleviate this problem, each memory cell in the DRAM must be periodically read, sensed, and re-written to a full level, generally requiring additional circuitry. Additionally, in order to increase the capacitive storage capability, the capacitors may be designed to a larger scale. The plates must be large enough to retain the energy level without being detrimentally affected by parasitic components or device noise.

However, as technology advances and smaller, faster devices are being implemented, the use of planar capacitor limits the scaling of DRAM cells. In particular, the packing density of DRAM cells is reduced and therefore, the number of available memory cells on a wafer is limited.

Another example of a random access memory device includes a static random access memory (SRAM) cell, which does not require the refresh operations like a DRAM memory cell. The SRAM cell can retain the stored information and consumes very little power during its standby state. However, the density of the storage elements in the SRAM is low compared to the density of the storage elements in the DRAM.

Any shortcoming mentioned above is not intended to be exhaustive, but rather is among many that tends to impair the effectiveness of previously known techniques for memory storage design however, shortcomings mentioned here are sufficient to demonstrate that the methodologies appearing in the art have not been satisfactory and that a significant need exists for the techniques described and claimed in this disclosure.

### SUMMARY OF THE INVENTION

The present disclosure provides a three-dimensional, single transistor memory cell, which is considerably smaller in terms dimension compared to standard six transistor memory devices, and thus, allows for increased memory cell availability on a wafer.

In one respect, a three-dimensional capacitor may be coupled to a drain input of a multi-gate field effect transistor (MUGFET). The MUGFET may include a multi-fin MUGFET and the three-dimensional capacitor may be a multi-fin three-dimensional capacitor.

In other respects, a three-dimensional capacitor may be coupled to a drain input of a fin field effect transistor (finFET). The three-dimensional capacitor may be a multi-fin three-dimensional finFET type capacitor.

In some respects, a method for fabricating a single-transistor memory cell is provided. The method includes providing a substrate, such as an SOI substrate, bulk silicon substrate, strained silicon-on-insulator (sSOI) substrate, silicon-germanium-on-insulator (GOI) substrate, strained silicon-germanium-on-insulator (sGeOI) substrate, or silicon on sapphire (SoS) substrate. Next, the method provides steps for defining a source and drain and forming a channel between the source and drain and a gate area on the substrate.

The method also provides forming a first and second capacitor plate of a three-dimensional capacitor coupled to the drain of the transistor. In some embodiments, the first capacitor plate may be fabricated simultaneously with the step of forming the channel. Similarly, the second capacitor plate may be fabricated substantially simultaneously with the step of defining the gate area of the transistor.

### BRIEF DESCRIPTION OF THE DRAWINGS

The following drawings form part of the present specification and are included to further demonstrate certain aspects of the present invention. The figures are examples only. They do not limit the scope of the invention.

FIG. 1 is a circuit diagram of a single transistor memory device, in accordance with embodiments of this disclosure.

FIG. 2 is a layout diagram of a single transistor memory device of FIG. 1, in accordance with embodiments of this disclosure.

FIG. 3 is a semiconductor structure including a MuGFET and a capacitor box, in accordance with embodiments of this disclosure.

FIG. 4 is the semiconductor structure of FIG. 3 with a gate oxidation layer and a lower plate of the capacitor box, in accordance with embodiments of this disclosure.

FIG. 5 is the semiconductor structure of FIG. 4 with spacer isolation, in accordance with embodiments of this disclosure.

FIG. 6 is the semiconductor structure of FIG. 5 with a source and drain definition, in accordance with embodiments of this disclosure.

FIG. 7 is the semiconductor structure of FIG. 6 with silicide formation, in accordance with embodiments of this disclosure.

FIG. 8 is a substrate including a multiple fin capacitor and MUGFET, in accordance with embodiments of this disclosure.

FIG. 9 is a substrate including a multiple fin capacitor and multiple fin MUGFET, in accordance with embodiments of this disclosure.

FIGS. 10A, 10B, and 10C are cross-sectional views of different transistors used in a single transistor memory cell, in accordance with embodiments of this disclosure.

### DESCRIPTION OF ILLUSTRATIVE EMBODIMENTS

The disclosure and the various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only and not by way of limitation. Various substitutions, modifications, additions, and/or rearrangements within the spirit and/or scope of the underlying inventive concept will become apparent to those skilled in the art from this disclosure.

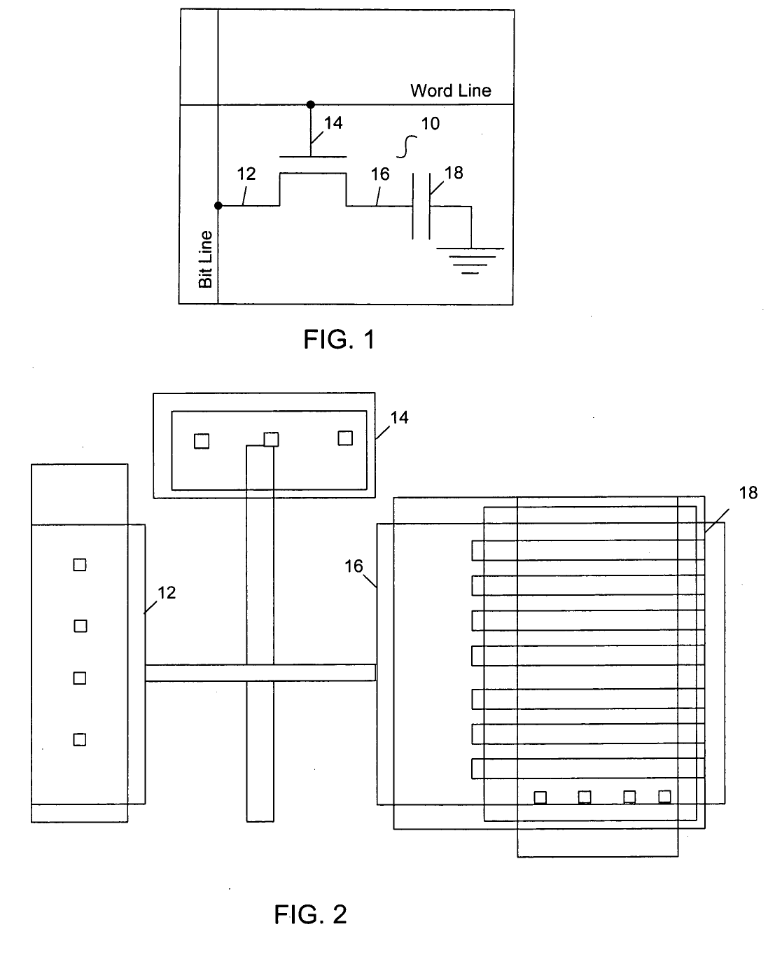

The disclosure provides a memory cell having one transistor coupled to a capacitor, as shown in the circuit diagram and corresponding layout of FIG. 1 and 2, respectively. Transistor 10 may include source terminal 12 coupled to a bit line, gate terminal 14 coupled to a word line, and drain terminal 16 coupled to capacitor 18. In one embodiment, transistor 10 may be formed on substrate such as a silicon on insulator (SOI) substrate, bulk silicon substrate, or any substrate used in FET fabrication.

In one embodiment, transistor 10 may be a multi-gate field effect transistor (MUGFET) on a SOI substrate. Alternatively, transistor 10 may be a Fin field effect transistor (finFET), a Π transistor, or an Ω transistor. The fabrication process of transistor 10 and capacitor 18 may be done using conventional techniques known in the art, and thus provides an inexpensive technique compared to other fabrication processes.

Referring again to FIG. 1, capacitor 18 may be a three-dimensional capacitor with a fin-type structure. This fin-type structure may increase the total capacitor area. In one embodiment, capacitor 18 may be substantially equivalent to a planar 1.1 micrometer-square capacitor, but can have a larger layout, e.g., the height of a 3D capacitor allows the capacitor to have a larger layout compared with a planar capacitor. For example, a fin capacitor with a one to one (1:1) pitch on 880 Angstrom silicon on insulator (SOI) may have an effective area of about 27.6 micrometer-square, approximately 25 times the area of a planar capacitor. The larger area capacitor may store charge more effectively and reliably. Additionally, the area efficiency for the memory cell improves since the cell density increases due to three dimensional use of the chip.

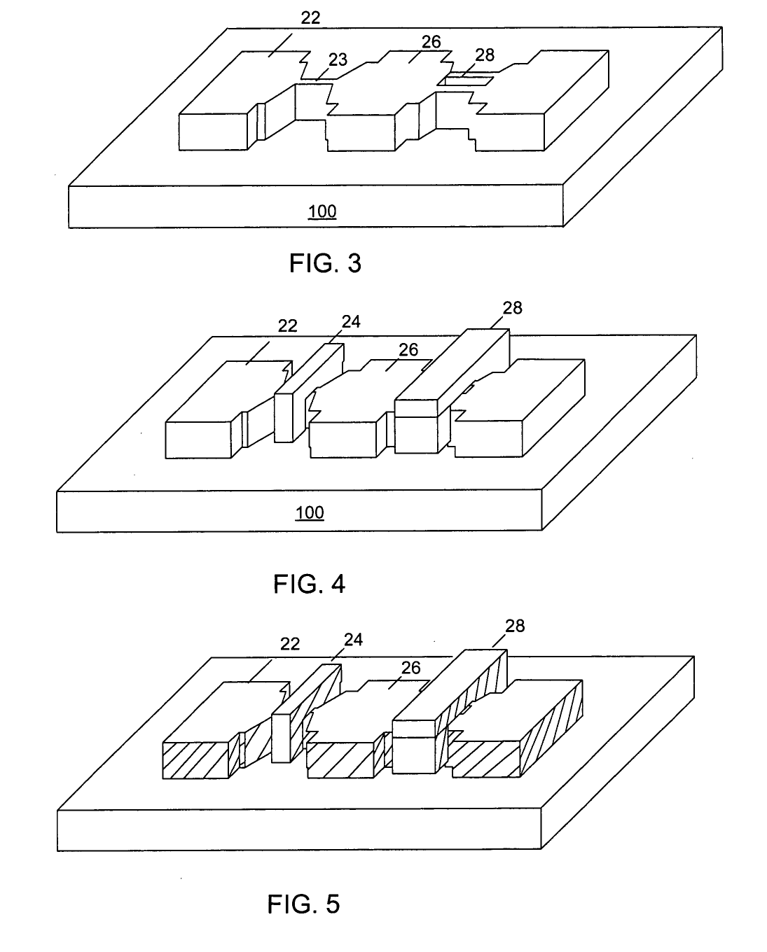

Referring to FIGS. 3-7, a method for fabricating a one transistor memory device is shown. The fabrication of the one-transistor memory device and a three-dimensional capacitor does not require additionally fabrication steps, and thus, provides advantages over the standard multi-transistors memory cell. In one embodiment, an active area of the transistor, in this an embodiment, a MUGFET, includes channel 23, source 22, drain 26, and a first capacitor plate for capacitor 28 may be formed on substrate 100, as shown in FIG. 3. Substrate 100 may include, without limitation, an SOI substrate, bulk silicon substrate, strained silicon-on-insulator (sSOI) substrates, silicon-germanium-on-insulator (GOI) substrates, strained silicon-germanium-on-insulator (sGeOI) substrates, silicon on sapphire (SoS) substrates, or any other substrates used in FET fabrications.

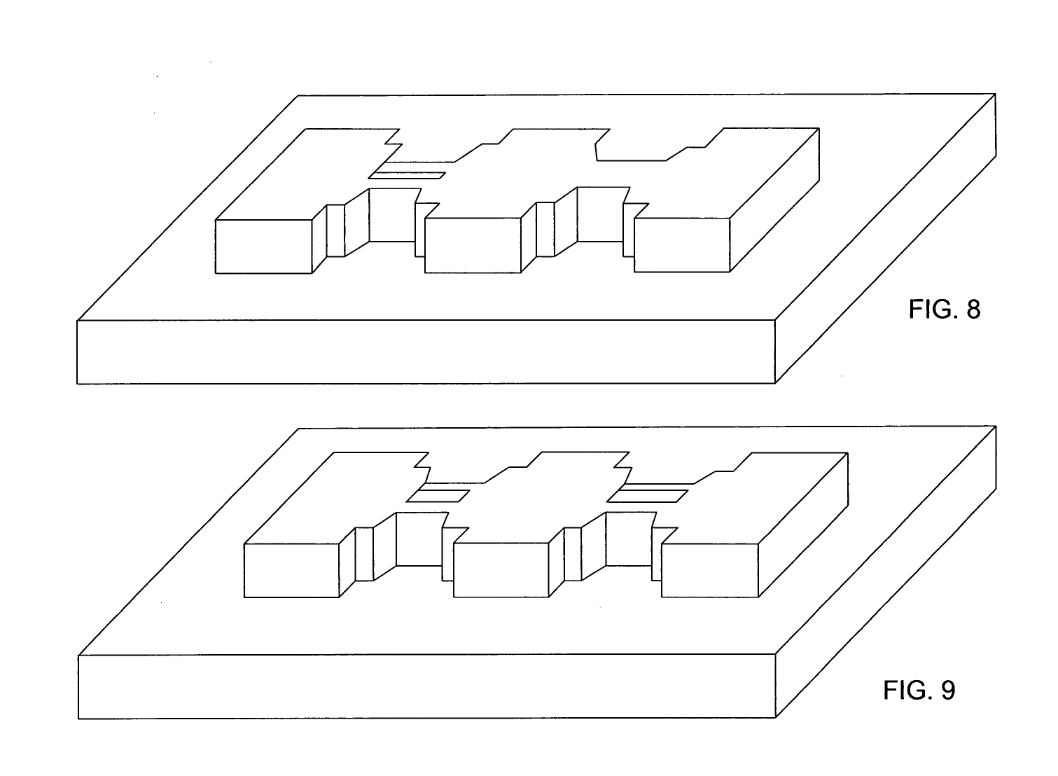

In some embodiments, capacitor 28 may include a single fin capacitor coupled to a multiple fin MUGFET as shown in FIG. 8. Alternatively, capacitor 28 may include a multiple fin capacitor coupled to multiple fin MUGFET as shown in FIG. 9.

Those with ordinary skill in the art may understand that fabrication steps including, without limitation, chemical vapor deposition (CVD), atomic layer deposition (ALD), wet etch, dry etch, etc., may be used. In one embodiment, to form channel 23 of a MUGFET and the capacitor bottom plate (e.g., the capacitor plate coupled to a terminal of a transistor) simultaneously, an implantation step may be done in the silicon on the buried oxide. One of ordinary skill in the art may recognize that the channel and the capacitor bottom plate may be fabricated separately, using for example, extra masking steps. Using an appropriate lithography process such as 248 nm, 193 nm, e-beam, spacer process, etc., a resist layer may be deposited and patterned such to define the fin, the source area, and drain area of the transistor. Additionally, the resist may be pattered to define the capacitor top plate and the contact area. The size of MUGFET may correspond to the minimum feature sizes varying for different implementations. Next, the silicon layer of substrate 100 may be etched using an etchant selective to the buried oxide. The resist layer may be ashed and the features are cleaned using for example, a wet cleaning solution (SPM/RCA) or Excalibur clean process.

In some embodiments, the transistor and capacitor 28 may be fabricated using films requiring a hard mask. The hard mask may be patterned using a photo resist layer and an anti-reflective coat layer. Next, the hard mask is then used to etch the silicon feature and stopped on the buried oxide.

In some embodiments, the first capacitor plate for capacitor 28 may be formed with a hydrogen (H₂) anneal process, such that the interface roughness of the transistor and capacitor 28 is reduced. A H₂ anneal may smooth the fin surfaces and round the exposed sharp corners. The hydrogen anneal process may be performed at about 800° C. and about 600 Torr or closer to atmospheric pressure may be more suitable for MuGFET structure and may be used for capacitor structures.

One of ordinary skill in the art will recognize that other sidewall smoothness methods may be used. For example, various oxidations of the etched surface and a selective wet strip may be used to smooth the sidewalls.

Next, a gate dielectric and polysilicon may be deposited and patterned to form gate 24 and the top plate of capacitor 28 (e.g., the capacitor plate coupled to ground as shown in FIG. 1), respectively, as shown in FIG. 4. One of ordinary skill in the art will recognize that the channel and the capacitor bottom plate may be fabricated separately, using for example, extra masking steps. In some embodiments, the gate dielectric may include, without limitations, silicon dioxide, high-k dielectric layer, silicon nitride, or any other dielectric layers. The polysilicon may include, for example, a polycrystalline silicon, amorphous silicon, metal gate, or any combination of the above listed. Techniques, such as, but not limited to, wet or dry gate oxidation may be used to form the gate dielectric layer for gate 22 and techniques such as, but not limited to, chemical vapor deposition may be used to deposit the polysilicon. Additionally, for multiple gate control, the gate dielectric thickness may be increased to substantially match with the capacitor thickness.

In FIG. 5, spacers may be formed on the resulting structure of FIG. 4. In one embodiment, spacers may be formed to isolate gate 24 from source 22 and drain 26. Fabrication steps, such as, but not limited to, an anisotropic etch selective to oxide (top layer of source 22 and drain 26) may be used to remove part of the sidewalls to form the spacers. Capacitor 28 may be connected to the drain of the FET under the spacer and continuous to the top plate.

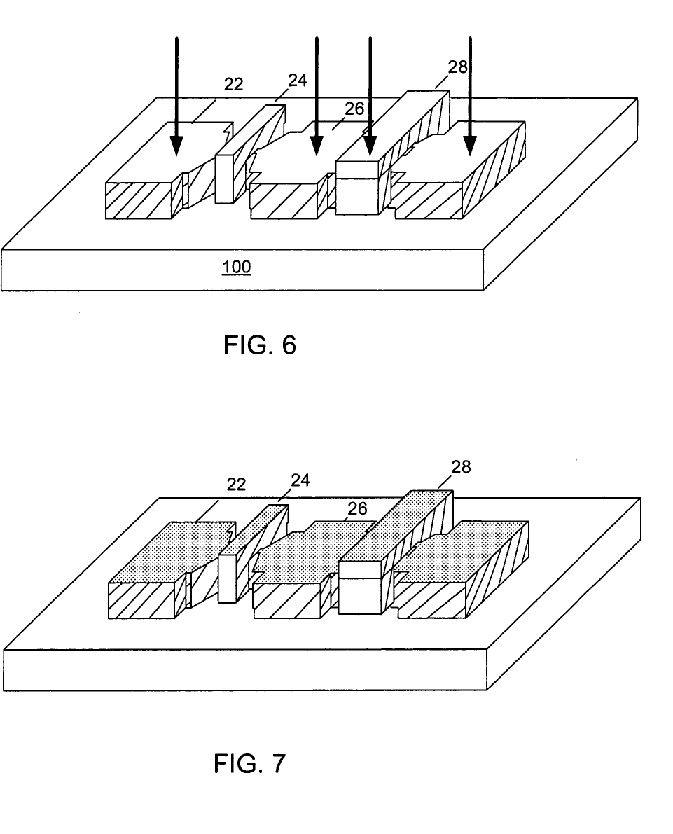

Next, the source and drain may be defined, as shown in FIG. 6. In one embodiment, a mask layer may be used to protect drain 26 while an n-type ion may be implanted to create the source region. Similarly, after the removal of the mask layer protecting drain 26, another mask layer may be used to protect source 22, and a p-type ion may be implanted to create the drain region. Additionally, the lower plate of capacitor 38 may be implanted using techniques known in the art.

In FIG. 7, silicide formation may be performed on the resulting structure in FIG. 6 to form contacts. In one embodiment, a silicide block may be used to avoid silicidation at the transistor. The capacitor node, polysilicon, and other silicon openings may be subjected to a deposition and thermal treatment of a film, including, without limitation, CoSi₂, HiSi₂, MoSi₂, NiSi₂, Pd₂Si, PiSi, PtSi, TaSI₂, TiSi₂, WSi₂, or ZrSi₂ to form contact landings.

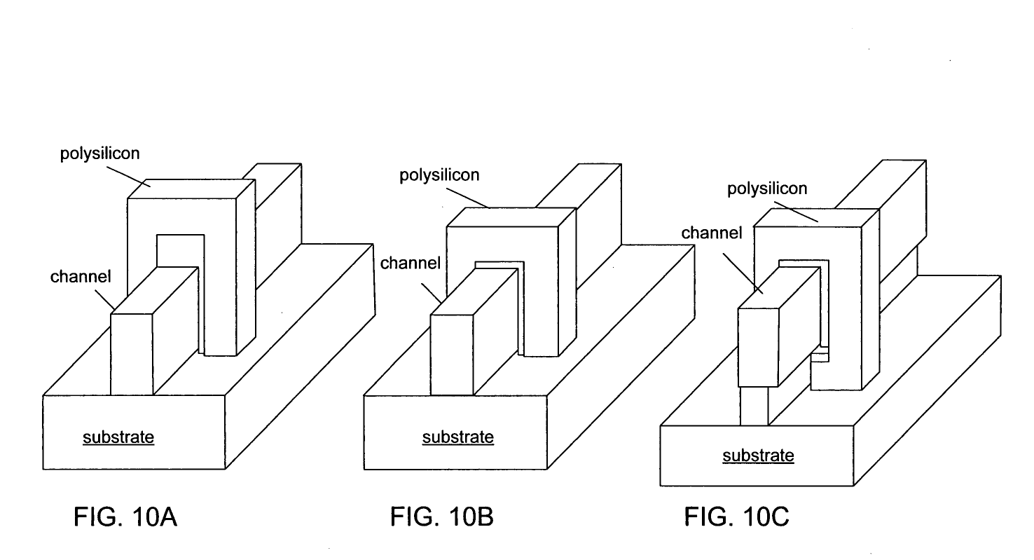

Similar fabrication steps such as those shown in FIGS. 3 through 7 may be used to create other one-transistor memory cell having a 3D capacitor. For example, referring to FIGs. 10A, 10B, and 10C, a cross-sectional view of finFET, a tri-gate transistor, and a Π or Ω transistor that may be used in a one-transistor memory cell is shown, respectively. The integration and optimization of the 3D capacitor coupled to the structure shown in FIGs. 10A-10C that requires no extra mask as compared to CMOS process and offers substantial area advantages over conventional memory cells.

Additionally, the above fabrication steps may also be used to create a plurality of one transistor memory cells. The plurality of one transistor memory cells may be coupled, for example, in series to form a memory cell system.

All of the methods and devices disclosed and claimed can be made and executed without undue experimentation in light of the present disclosure. While the methods of this invention have been described in terms of embodiments, it will be apparent to those of skill in the art that variations may be applied to the methods and in the steps or in the sequence of steps of the method described herein without departing from the concept, spirit and scope of the invention. All such similar substitutes and modifications apparent to those skilled in the art are deemed to be within the spirit, scope, and concept of the disclosure as defined by the appended claims.

1. A memory circuit comprising a multi-gate field effect transistor and a fin capacitor coupled to a drain of the multi-gate field effect transistor.

2. The memory circuit of claim 1, the fin capacitor comprising a three-dimensional fin capacitor.

3. The memory circuit of claim 1, the multi-gate field effect transistor comprising a multiple fin multi-gate field effect transistor.

4. A memory circuit comprising a fin field effect transistor and a three-dimensional capacitor coupled to a drain of the fin field effect transistor.

5. The memory circuit of claim 4, the fin capacitor comprising a three-dimensional fin capacitor.

6. The memory circuit of claim 4, the multi-gate field effect transistor comprising a multiple fin multi-gate field effect transistor.

7. A method for fabricating a single-transistor memory cell, comprising:
providing a substrate;
defining a source and a drain of a transistor on the substrate;
forming a channel between the source and drain of the transistor;
forming a first plate of a fin capacitor;
defining a gate area of the transistor; and
forming a second plate of the fin capacitor, where the three-dimensional capacitor is coupled to the drain of the transistor.

8. The method of claim 7, further comprising creating spacers to isolate the gate from the source and drain.

9. The method of claim 7, the fin capacitor comprising a three-dimensional fin capacitor.

10. The method of claim 7, the substrate being selected from the group consisting of an SOI substrate, bulk silicon substrate, strained silicon-on-insulator (sSOI) substrate, silicon-germanium-on-insulator (GOI) substrate, strained silicon-germanium-on-insulator (sGeOI) substrate, and silicon on sapphire (SoS) substrate.

11. The method of claim 7, the transistor being selected from the group consisting of a multi-gate field effect transistor, a fin field effect transistor, a tri-gate transistor, a Π transistor, and a Ω transistor.

12. The method of claim 7, the step of forming the channel and the step of forming the bottom plate being substantially simultaneous.

13. The method of claim 7, the step of defining a gate area and the step of forming the second plate being substantially simultaneous.
